(19) United States
(12) Patent Application Publication
(10) Pub. No.: US 2011/0164754 A1
(43) Pub. Date: Jul. 7, 2011

(54) Loudspeaker Device

(76) Inventors: Achim Gleissner, Diekholzen (DE); David Paul Theis, Middletown, CA (US); Suzanne Fiona Sielski Waters, Kent (GB)

(21) Appl. No.: 12/743,561

(22) PCT Filed: Nov. 27, 2008
(86) PCT No.: PCT/EP08/10047

§ 371 Date: Nov. 19, 2010

(30) Foreign Application Priority Data
Nov. 28, 2007 (DE) 10 2007 057 664.3

(51) Int. Cl. H03G 3/20; H04R 5/00

(52) U.S. Cl. 381/17; 381/57

(57) ABSTRACT

There is provided a loudspeaker device comprising at least one loudspeaker (L1, L2) for the playback of audio signals and at least one microphone (M1, M2) for recording ambient noises. The loudspeaker unit further has an audio input (D1) for receiving audio signals to be played back and a signal processing unit (DSP) for controlling the playback of the audio signals to be played back by the at least one loudspeaker (L1, L2) in dependence on the ambient noise recorded by the at least one microphone (M1, M2).

The present invention concerns a loudspeaker device.

Whereas hitherto loudspeakers were typically provided in the form of passive loudspeakers and were connected to a central amplifier, decentral loudspeakers with integrated amplifiers are also known.

Conventional loudspeaker systems only permit monitoring of loudspeakers by impedance measurement of the loudspeakers. In addition adaptation of the reproduction level to the ambient noises has to be effected manually and individual adaptation of individual loudspeakers is not readily possible. Adaptation to an ambient noise is often possible only by altering the volume level.

Loudspeaker systems are also known, in which a microphone records the ambient noise and feeds it in amplified form to the loudspeaker. In that case a noise in phase opposition relationship is generated, which counteracts the interference signal (noise canceling).

Therefore an object of the present invention is to provide a loudspeaker device which can be put to versatile uses and which can output an improved output signal.

That object is attained by a loudspeaker device as set forth in claim 1 and by a method of controlling a volume device as set forth in claim 1.

Thus there is provided a loudspeaker device comprising at least one loudspeaker or electroacoustic transducer for the playback of audio signals and at least one microphone for recording ambient noises. The loudspeaker unit further has an audio input for receiving audio signals to be played back and a signal processing unit for controlling the playback of the audio signals to be played back by the at least one loudspeaker in dependence on the ambient noise recorded by the at least one microphone.

In that way the loudspeaker device can automatically adapt the playback of the audio signals to the prevailing ambient conditions. For example the level of playback of the audio signals can be increased if the level of the ambient noises rises. In a corresponding fashion the level of the audio signal to be played back can be lowered if the level of the ambient noises falls.

In accordance with an aspect of the present invention the signal processing unit is adapted to adapt the volume level and/or a frequency-dependent amplification of the signal to be played back in dependence on the ambient noise recorded by the at least one microphone.

In accordance with a further aspect of the present invention the audio signal to be played back is added to the ambient noise recorded by the at least one microphone and outputted to achieve adaptive masking of the ambient noises.

In accordance with a further aspect of the present invention the audio input is in the form of an interface or has an interface, by way of which status information in respect of the loudspeaker unit and/or in respect of the ambient noise recorded by the at least one microphone can be communicated to an external central unit.

In accordance with a further aspect of the present invention the loudspeaker unit according to the invention can be in the form of a local sound radiation unit.

The invention also concerns a method of controlling a loudspeaker device. In that case ambient noises are recorded by means of at least one microphone. Audio signals to be played back are received at an audio input. Playback of the audio signals to be played back is controlled in dependence on the ambient noises recorded by the at least one microphone.

The invention concerns the concept of providing a microphone in or at a loudspeaker, wherein the microphone records both the sound delivered by the loudspeaker and also the ambient sound. Those items of information are passed to an analog or digital signal processing unit which serves to influence playback of an audio signal by the loudspeaker based on the signals recorded by the microphone. Optionally a control signal or items of control information can be communicated from the loudspeaker to a central unit. The loudspeaker device further has an input for audio signals, for example from a central unit.

The invention thus concerns a loudspeaker device comprising at least one loudspeaker and at least one microphone and a signal processing unit. The loudspeaker unit further has an audio input for receiving audio signals. The signals recorded by the microphone are fed to the analog or digital signal processing unit and the output signal of the loudspeaker is controlled by the signal processing unit. The microphone of the loudspeaker device detects the sound field in the region of the loudspeaker. The output signal of the microphone is passed to the signal processing unit which serves to control the loudspeaker based on predetermined algorithms. In that way the loudspeaker signal can be adapted to the ambient noise. In addition the functions of the loudspeaker can be monitored. Furthermore space monitoring is possible, without a loudspeaker signal. Furthermore given functions and control signals can be triggered in dependence on the ambient situation.

The invention concerns an adaptive system which permits direct utilization of the microphone signal within a loudspeaker module. The adaptive system can have a multiplicity of the above-described loudspeaker devices. The adaptive system can distribute the audio signals to be played back to the respective loudspeaker devices. That can be effected both in wired and also wireless mode. The adaptive system can also have a central unit. The individual loudspeaker modules can be individually adapted. The loudspeaker module can be provided with a data connection so that further functions are made possible.

Further configurations of the invention are subject-matter of the appendant claims.

Embodiments by way of example and advantages of the invention are described in greater detail hereinafter with reference to the drawing.

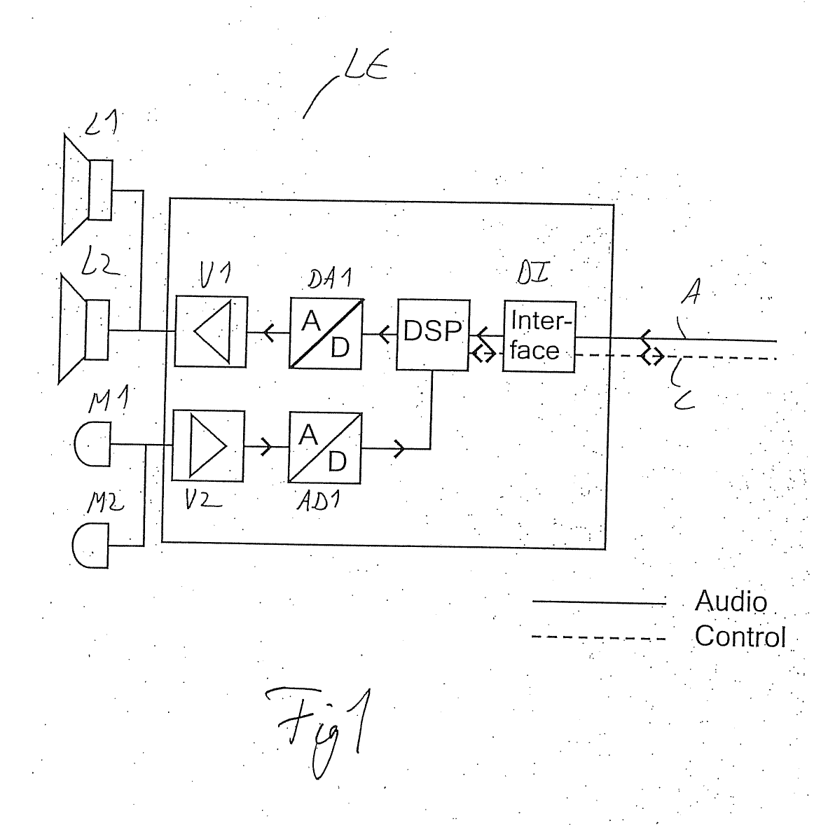

FIG. 1 shows a schematic block circuit diagram of a loudspeaker device in accordance with a first embodiment.

FIG. 1 shows a schematic block circuit diagram of a loudspeaker device in accordance with a first embodiment. The loudspeaker device in accordance with the first embodiment has an interface DI, a (digital) signal processing unit DSP, a digital/analog converter DA1, a first amplifier V1, a second amplifier V2 and an analog/digital converter AD1. The interface DI is adapted to receive an audio signal A. The interface DI is further adapted to receive a control signal C and send a further control signal. A first and/or second loudspeaker L1, L2 and/or a first and second microphone M1, M2 can be provided in or at the loudspeaker unit LE. Alternatively thereto more than two loudspeakers and/or more than two microphones can also be correspondingly used. The signal processing unit DSP is preferably in the form of a digital signal processor and can evaluate the ambient audio signals recorded by the first and/or second microphone M1, M2 (which were amplified by the second amplifier V2 and subjected to analog/digital conversion by the A/D converter) and influence the audio signal outputted by the first and/or second loudspeaker L1, L2. The digital signal processor DSP can also be adapted to decode the coded audio signal so that the decoded audio signals can be outputted by way of the first and/or second loudspeaker L1, L2. A transmitting device for transmitting and receiving items of status information and/or control signals can be provided in the digital signal processor DSP and/or in the interface DI. The audio signals recorded by the two microphones can also be communicated to a central unit by way of the interface DI.

The audio signals recorded by the microphones can be evaluated by the digital signal processor DSP. Alternatively thereto the audio signals recorded by the microphones M1, M2 can be evaluated by an external central unit. The useful signal of the loudspeakers L1, L2 can be adapted by the digital signal processor DSP in dependence on the ambient signals recorded by the microphones M1, M2. In that case both the level can be adapted and also frequency-dependent amplification (equalizing) can be carried out.

Self-regulation of the level or the frequency-dependent amplification can be effected by adaptive adaptation of the level and/or the frequency-dependent amplification.

A maximum level of the useful signal can be stored in the digital signal processor DSP so that it is possible to prevent the volume level of the loudspeaker unit becoming too high.

If the position of the microphone in relation to the loudspeaker unit is known the system can be appropriately calibrated.

The status of the loudspeaker unit can be monitored by the microphones and the items of status information can optionally be communicated by way of the interface DI to a central unit.

The adaptive loudspeaker unit and the microphone arranged therein or thereat can provide that for example speech can be locally detected within the system for example in a lecture situation and amplified.

The ambient noises can be detected by means of the microphones. If the ambient noises exceed a given volume (for example a train going past at a station) then the digital signal processor can be adapted to speak and repeat the signal to be played back or an announcement, which for example would not be understood because of the ambient noise. That aspect of the invention can also be used for announcements in a fair or exhibition environment, at an airport, at a ferry terminal, in a bus station or the like.

Noise masking can be achieved by means of the loudspeaker device according to the invention. For that purpose an adaptive masking noise is produced and reproduced in dependence on the ambient volume and position. That is of use for example in an open-plan office to cover up the speech signals. Thus noise masking can be effected in adaptive relationship with the actual volume.

The loudspeaker device according to the invention can also be used as an alarm system, in which case acoustic monitoring can be effected by the microphones M1, M2. If it is established by acoustic monitoring that an alarm condition has occurred, that can be communicated to a central unit by means of the interface DI. In addition to the microphones motion sensors can be provided at the loudspeaker unit so that not just acoustic monitoring but also motion monitoring can be effected. Acoustic monitoring and/or motion monitoring can be coupled to triggering of audio playback.

In accordance with a further embodiment of the invention the loudspeaker unit can be provided with a codable receiving device, for example a transponder. For example controlled playback of audio signals can be effected by means of the transponder in dependence on an item of transmission information. In dependence on items of information which are transmitted by way of a data bus, playback of items of information can be effected in different languages.

The useful signal of the loudspeaker can be subtracted from the ambient signals in the digital signal processor DSP in order to determine the interference signals when the position of the loudspeaker and of the microphone are known. Alternatively or additionally thereto the interference signals can be determined in the pauses in the useful signals.

According to the invention a regulating circuit can be afforded by the loudspeakers L1, L2, the microphones M1, M2 and the digital signal processor.

In accordance with an embodiment of the invention the audio signals recorded by the microphones are passed only to the digital signal processing unit DSP and not to an external central unit.

FIG. 1 shows the loudspeaker unit LE with the microphones and loudspeakers. According to an alternative embodiment the loudspeaker unit LE can also be provided without internal loudspeakers and/or microphones. In such a case the loudspeaker unit LE has a connection for loudspeakers and a connection for microphones.

The loudspeaker device according to this embodiment has a setup mode of operation, in which case the system can be calibrated by means of a pulse.

According to the invention the ambient noises recorded by the microphones are preferably not used to implement active noise reduction, but they are only used to influence the volume, frequency or the like of the audio signal to be played back. If for example it is detected by the microphones that the level of the ambient noises in a room has fallen then in accordance with the invention the level of the audio signals to be played back can also be adaptively lowered.

Although in the foregoing embodiment a digital signal processing unit has been described the invention can also be implemented with an analog signal processing unit. Possibly in that case the digital/analog converter or the analog/digital converter can be omitted.

Adaptation of the audio signal to be outputted to the ambient noise can be effected with the loudspeaker device according to the present invention. That can be effected for example by altering the volume level and/or by frequency-dependent amplification.

A maximum useful level can also be set by means of the loudspeaker device according to the invention.

A motion monitoring system can be implemented by means of the loudspeaker device according to the invention, for example by motion sensors being provided at or in the loudspeaker unit. In that case the outputs of the motion sensors can be passed by way of the interface DI to a central unit where they are appropriately evaluated. Alternatively thereto the signals of the motion sensors can also be evaluated in the signal processing unit and optionally an alarm signal can be outputted by way of the loudspeakers. That alarm signal can be produced for example by the signal processing unit.

The loudspeaker device according to the invention can have an operating element with which the volume level and/or the frequency-dependent amplification of the loudspeaker unit can be adjusted. The loudspeaker device can also optionally have further audio inputs so that further audio signals can be inputted to the loudspeaker unit LE and can be outputted thereby. In accordance with that aspect of the invention the loudspeaker device can be used as a local sound radiation installation or as a PA installation.

The above-described signal processing unit can be implemented both in digital and also analog form. If the signal processing unit is implemented in analog form the digital/analog and analog/digital converters shown in FIG. 1 can be omitted.

In accordance with a further embodiment there is provided a loudspeaker system comprising a multiplicity of the above-described loudspeaker devices and a central unit. The central unit can serve to supply the multiplicity of loudspeaker devices with an audio signal to be played back. In addition items of control information and/or signals of the microphones of the loudspeaker devices can be communicated to the central unit from the respective loudspeaker devices. Those items of information can have for example items of status information in regard to the loudspeaker unit and/or in regard to the ambient noises. Those items of information can further have items of information in regard to the operational capability of the loudspeaker device, which have been detected or determined by the signal processing unit in the respective loudspeaker device.

The ambient noises detected by the microphones in the loudspeaker device can be entirely or partially passed to the central unit where they can be used for space monitoring.

The central unit can further be adapted to communicate coded audio signals to the respective loudspeaker devices, in which respect the coded audio signals can be decoded only by that loudspeaker device for which they are intended. That loudspeaker device can then output the received and decoded audio signals by means of the internal or by means of an external loudspeaker.

Communication between the central unit and the loudspeaker devices can be wired or wireless.

1. A loudspeaker device comprising:
at least one loudspeaker for the playback of audio signals,
at least one microphone for recording ambient noises,
an audio input for receiving audio signals to be played back, and
a signal processing unit for controlling the playback of the audio signals to be played back by the at least one loudspeaker in dependence on the ambient noises recorded by the at least one microphone.

2. A loudspeaker device as set forth in claim 1 wherein the signal processing unit is adapted to adapt the level and/or a frequency-dependent amplification of the audio signal to be played back in dependence on the ambient noise recorded by the at least one microphone.

3. A loudspeaker device as set forth in claim 1 wherein the audio signal to be played back is added to the ambient noise recorded by the at least one microphone and outputted to achieve adaptive masking of the ambient noises.

4. A loudspeaker device as set forth in claim 1 wherein the audio input is in the form of an interface, by way of which status information in respect of the loudspeaker unit and/or in respect of the ambient noise can be communicated to an external central unit.

5. A loudspeaker device as set forth in claim 4 wherein the signal processing unit is adapted to monitor the operational capability of loudspeaker device based on the ambient noise recorded by the at least one microphone.

6. A loudspeaker device as set forth in claim 1 wherein the ambient noise recorded by the at least one microphone is monitored by the signal processing unit to permit space monitoring.

7. A loudspeaker device as set forth in claim 1 wherein adjustment of the maximum useful level is effected.

8. A loudspeaker device as set forth in claim 1 wherein the signal processing unit is adapted to repeat a signal to be played back if the detected ambient noises exceed a given volume.

9. A loudspeaker unit as set forth in claim 1 and further comprising:
at least one operating unit for operating the loudspeaker unit, wherein the operating unit is adapted to adjust the level of the audio signal to be played back and/or to adjust a frequency-dependent amplification of the audio signal to be played back.

10. A loudspeaker unit comprising:
at least one first connection for the connection of a microphone,
a second connection for receiving audio signals to be played back,
a first output for the output of audio signal, and
a signal processing unit for controlling the audio signals outputted by the first output, in dependence on signals of the at least one microphone, that are received by the first connection.

11. A method of controlling a loudspeaker device comprising the steps:
recording ambient noises by means of at least one microphone,
receiving audio signals to be played back, and
controlling the playback of the audio signals to be played back in dependence on the ambient noises recorded by the at least one microphone.

12. A loudspeaker system comprising:
a central unit and a multiplicity of loudspeaker devices as set forth in claim 1, wherein the central unit supplies the plurality of loudspeaker devices with audio signals to be played back.
